(19) United States
(12) Patent Application Publication
(10) Pub. No.: US 2006/0181840 A1
(43) Pub. Date: Aug. 17, 2006

(54) Cradle for portable devices on a vehicle

(76) Inventor: Jonatan Cvetko, Harbor City, CA (US)

Correspondence Address: Maria Erlinda C. Sarno, Esq., P.O. Box 1023, Artesia, CA, 90702, US

(21) Appl. No.: 11/029,312

(22) Filed: Jan. 5, 2005

(51) Int. Cl. H05K 5/00

(52) U.S. Cl. 361/679

(57) ABSTRACT

A cradle including a main body with an opening for allowing a cable to go through and a cavity having an opening on a slanted bottom wall and supporting means for accommodating a portable device. A circuit board assembly supplies power, receives and transmits signals from the portable device to an external transmitting receiver device on a vehicle. A bottom lid may be used for enclosing the circuit board underneath the main body. Accessory adjusters can be placed on the main body to accommodate the different types and models of portable devices. This cradle is mounted or molded on an opening at a desired part of the vehicle to provided a seamless integration of the cradle, that is, without the presence of visible wires at the interior of the vehicle.

This invention relates to a cradle for holding a portable device in a vehicle. The ultimate concept is to be able to hold different portable devices that one carries on a road trip in a docking system or cradle permanently mounted in a vehicle whose cables are behind the interior of the vehicle to avoid dangling cables and also for aesthetic purpose. While one cradle can hold a particular device which is also a part of this invention, it is proposed to have a cradle with a universal main body that can accommodate different adjusters for the different types of portable devices. The cradle for a portable device of this invention, comprises a main body having side walls, an open bottom and a top cover, the top cover having a cavity for accommodating a portable device, the cavity having sidewalls and a downward slanting bottom wall having a front end lower than a back end to allow the portable device to insert into the cavity in a desired position, the sidewalls of the cavity having supporting means for keeping the portable device in an upright position, the main body having an opening on a wall for allowing a cable to go through and [[a slit]] at the downward slanting bottom wall of the cavity; a circuit board assembly comprising a first connector on one end of a circuit board inserting into the [[slit]] at the slanting bottom wall of the cavity and a second connector connected to the circuit board by the cable, the circuit board assembly supplying power, receiving and transmitting audio and data signals or both from the portable device to [[a radio system]] on a vehicle[[; and, a]]bottom lid for covering the open bottom of the main body after placement of the circuit board between within the main body and the bottom lid, the bottom lid [[having]] side walls, an open side facing the main body and a solid bottom wall. To enable the cavity on the main body to accommodate different types of portable devices or models of the same device such as the different models of a music player, an adjuster can be inserted into the cavity of the main body to fit the desired portable device or the particular model of the device having a particular size and shape. The adjuster can simply snugly fit into the cavity or it can have indents pairing with corresponding indents on the cavity for better fit and ease of repeated insertion and removal from the cavity. If an adjuster is used as a component of the cradle, the adjuster, instead of the main body, can have the supporting means for keeping the portable device in an upright position. It is also possible to design the adjuster without the supporting means and use the supporting means of the main body. The top cover of the main body has a lip protruding laterally beyond the side walls for suspending the main body of the cradle outside and above a desired part of the vehicle. For portable devices with front dials or buttons for operation or devices such as music players with a scroll wheel, a portion of a sidewall of the cavity facing the user is recommended to be etched out to provide unobstructed access to the scroll wheel, dials, buttons and the like of the particular device. The shape of the etching depend upon the set up of the dials and buttons. The etching is preferably in a convex shape for music players with a scroll wheel. Aside from the design of the cavity holding the portable device, it is recommended to provide additional support to the portable device while the portable device is inside the cavity. An example of a supporting means is a domelike extension providing a back support and for music players with a scroll wheel, raised ridges extending from the convex etching providing front support for the music player. Other structures extending from the top front side of the cavity can be used to provide front support. It is recommended to surround the [[slit]] at the slanted bottom wall of the cavity or the first connector, for example with raised ridges or fences to keep the first connector in an inclined upright position to facilitate the connection between the cradle and the portable device. The circuitry providing the electrical power to the cradle is situated underneath the slanting bottom wall of the cavity and the hollow interior of the main body which is one factor in keeping the cable connections from dangling outside the vehicle [[after t]] The bottom lid covers the main body thereby encasing this circuitry inside the cradle.

Aside from encasing the circuitry inside the cradle, as described above, to achieve a seamless integration of [[the]] a cradle with the portable device on the vehicle without the presence of visible wires dangling at the interior of the vehicle, it is recommended to disconnect or uninstall from the vehicle, a desired part of a vehicle where a portable device is desired. Here, an opening, on the part of the vehicle where the cradle will be mounted, is bored of a size just enough to accommodate the cabled main body of the cradle. The circuitry of the cradle is usually first installed inside the main body before mounting the cradle on the opening. The first connector for plugging into a music player is inserted through the [[slit]] at the slanted wall of the cavity and the circuit board connected to the first connector is held in place at the interior of the main body as stated above. A cable connected to the second connector is then inserted through the opening on the wall of the main body and connected to the circuit board. The main body with the circuitry is mounted on the opening bored at the desired part of the vehicle. The top cover of the main body is held on top of the outside surface of the part by laterally protruding elements on the main body having dimensions greater than the bored opening. After mounting the main body on the part, [[the]] bottom lid cover[[s]] the open bottom of the main body with the section of the part bordering the opening situated between the top cover of the main body and the bottom lid. The second connector of the circuit board assembly is then connected or plugged to an auxiliary port of the vehicle's radio system. The part is then reinstalled (if it had been disconnected previously) into the vehicle and the cradle is now ready for the operation after connecting the portable device to the first connector at the cavity of the main body. As stated above an adjuster for the cavity of the main body may be used to cater to the different types of portable devices and different models of the same portable device such as the different models of the music player having different sizes and shapes. However, another height and shape adjuster may be needed between the top cover of the main body and the part of the vehicle to accommodate the outside contour of the part, if the surface is not planar or if the shape of the bottom end of the main body is shaped differently from the outside contour. For example, if the part is the dashboard, the bottom end of the height and shape adjuster must fit and conform with the contour of the top surface of the dashboards which usually slope differently for each type or brand of the vehicle.

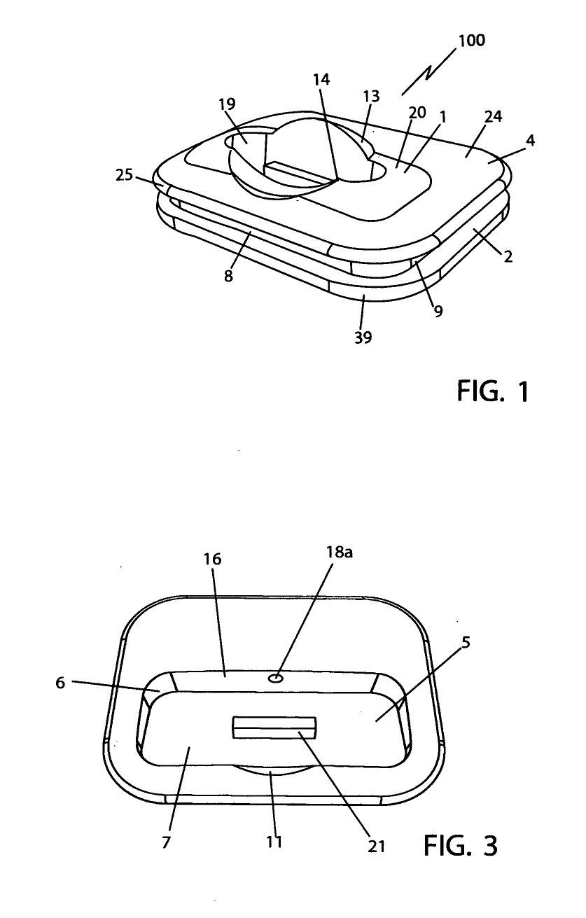

FIG. 1 is a perspective view of [[the]] cradle for a music player.

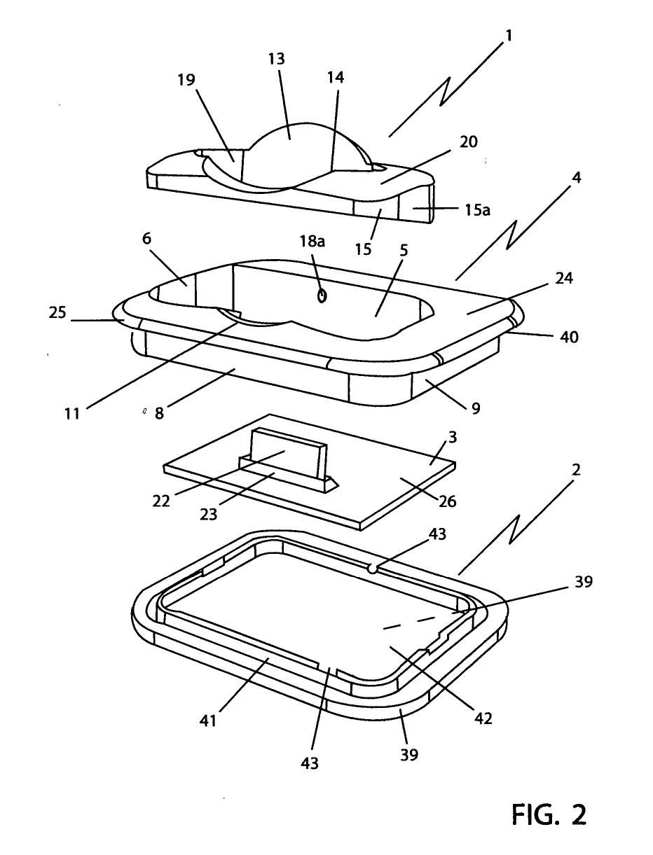

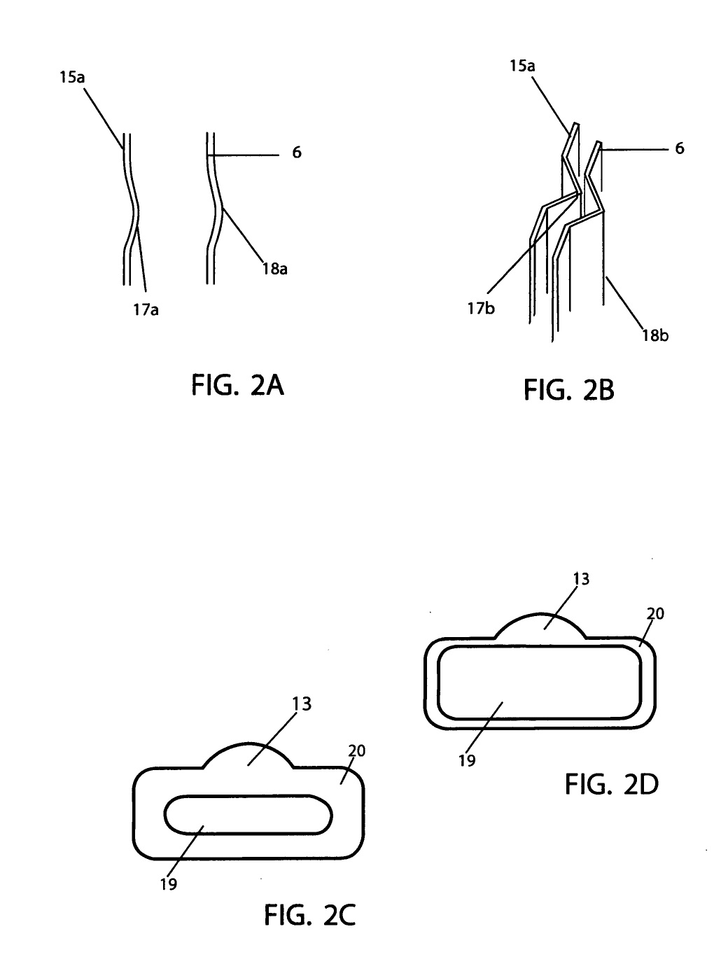

FIG. 2 is an exploded view of the cradle showing the major components.

FIG. 2A is a side view of a positive bump pairing with a negative bump indent.

FIG. 3 is a perspective front view of [[the]]main body.

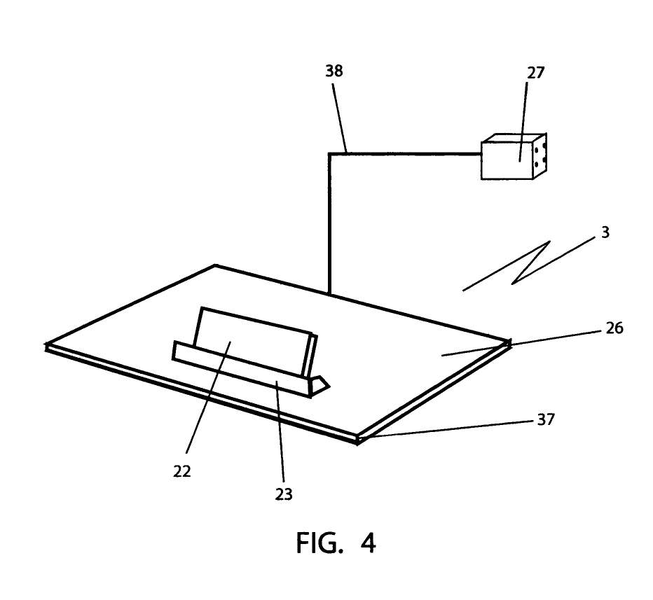

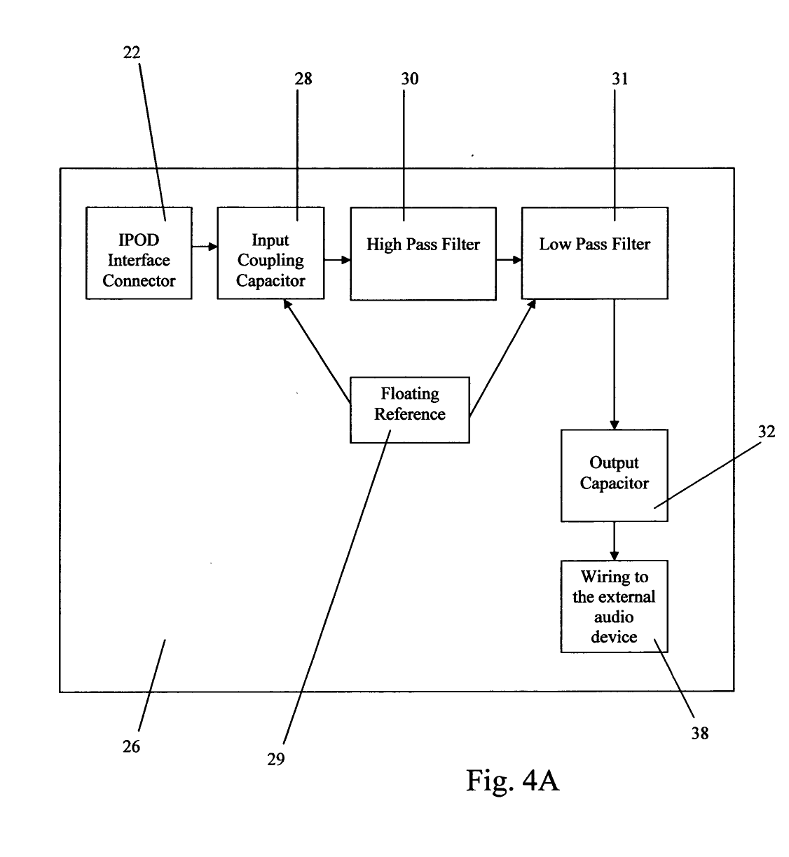

FIG. 4 is a perspective view of [[the]] circuit board assembly which includes the circuit board, cables and connectors.

FIG. 4A is a schematic diagram of [[the]] circuitry of [[the for]] a cradle for [[the]] music player.

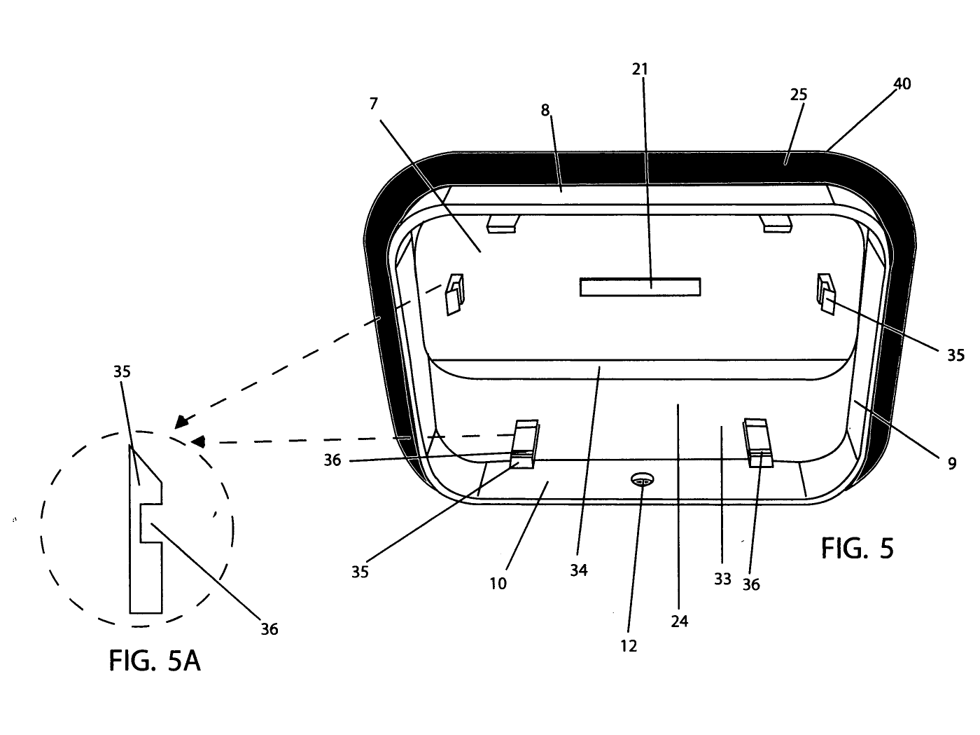

FIG. 5A is a perspective view of a clip for holding [[the]] circuit board.

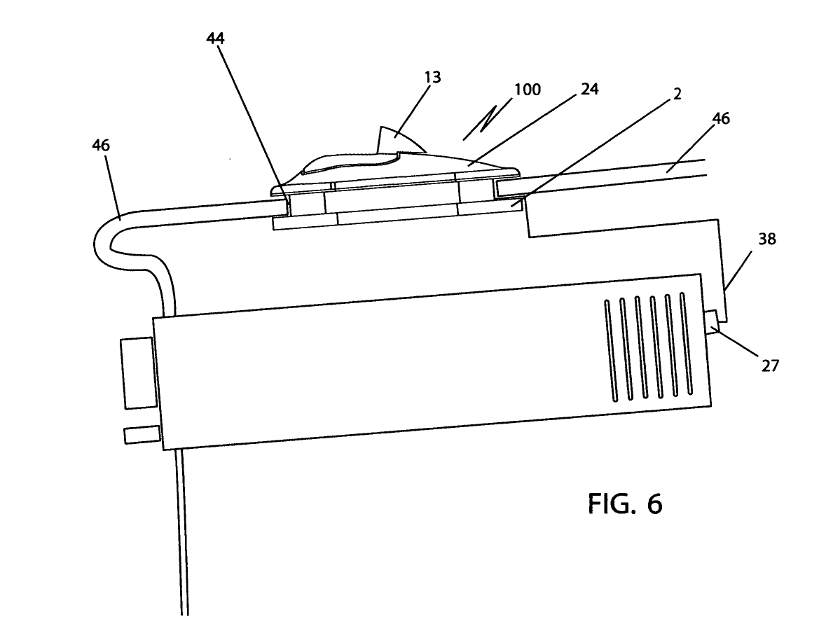

FIG. 6 is a cross section of an assembled cradle in a dashboard showing the cable directing inside the dashboard thereby avoiding any cable outside the [[car's]] interior.

FIG. 1 shows a perspective view of [[the]] cradle 100. It is essentially made of three components, with an interchangeable fourth component, herein identified as insert or adjuster 1, added for better fit, usage and flexibility. FIG. 2 shows an exploded view of the four components, a bottom lid 2, a circuit board assembly 3, a main body 4, and the adjuster 1. The adjuster 1 inserts within the main body 4. The adjusters would come in different dimensions and shapes depending upon the shape and size of the portable device such as a music player. The main body 4 may also be configured to directly accommodate the portable device without a need for an adjuster 1.

The ensuing description and illustration of the cradle has specific applications for an “IPOD” music player. “IPOD” is a registered trademark of Apple Computers, Inc. and herein will be represented according to the manufacturer's usage of the mark as Ipod. It should be noted, however, that the utility of the invention is not limited to the ipod, but rather extends to and encompasses other portable devices such as personal digital assistant, global positioning system devices, cell phones, digital video disk monitors, [[televison]] screens, monitor for electronic games, tablet personal computers, portable satellite radios and music players. The ipod music player is used herein to illustrate the claimed invention merely for convenience in describing the invention because of its widespread popularity and the users' familiarity with its operation. The main body 4 of the cradle 100 is shaped like a trough having a cavity 5 for accommodating the music player. The cavity is bordered with sidewalls 6 and a bottom wall 7 located within the main body as shown in FIG. 3. The bottom wall 7 is recommended to slant downwards with the front end lower than the back end to allow the music player to lay on the cavity in an inclined position which in turn allows the user to easily view the screen and control its operation. If the main body 4 is rectangular in shape, it would have a front wall 8, lateral side walls 9, and a back wall 10 which are better shown in FIG. 5. Although the main body can be shaped differently, the illustration herein is adopted for a rectangularly shaped main body. A portion 11 of the front wall is etched out in a convex shape to provide unobstructed access to the music player, in this case the scroll wheel (not shown) of the iPod. The etchings, as stated above, may be shaped differently to cater to a more universal usage aside from the iPod. The top of the sidewalls 6 of the cavity is flat except for the convex etching 11 as shown in FIGS. 2 and 3. A hole 12 as shown in FIG. 5 is bored through a wall of the main body such as the back wall 10 for accommodating a cable, an important feature of the claimed invention as will be described later. If the main body 4 is designed to directly accommodate a music player without a need for an adjuster 1, the top of the back wall 10 would have the upward domelike extension 13 (shown as part of the adjuster 1 in FIGS. 1 and 2) to provide better back support for the music player. Further, for music players with a scroll wheel, the respective edges of the convex etching 11 would be raised into ridges 14 to support the front of the music player (as shown in adjuster 1). For cradles where the adjuster 1 is used instead of the main body 4 to accommodate a music player, the domelike extension 13 and the ridges 14 are recommended to be configured into the adjuster 1 as shown in FIG. 2 for flexibility and ease of designing a more universal cradle that can accommodate the different adjusters. The adjuster does not have a bottom wall. The sidewalls 15 of the adjuster 1 is recommended but not necessary to assume the same shape as the sidewalls 6 of the cavity 5 of the main body 4, but of course, of a smaller dimensions in order to insert and fit into the cavity. It is recommended to have indents [[in]] this illustration, negative indents 18a at the interior face 16 of the sidewalls 6 of the cavity [[that]] matches with the indents 17a, illustrated as positive indents, at the exterior side 15a of the sidewalls 15 of the adjuster 1 to snug fit the adjuster 1 with the main body 4 when the adjuster is inserted into the main body. Indents herein are used to identify the many known structures that allow snapping or snug fitting of one body with another such a bump (positive indent) 17a on an exterior wall of one component fitting into an indentation 18a (negative indent) on the exterior wall of a second component at a location opposite each other. Instead of a bump, it may be a lateral protrusion 17b on one component lodging on an opposite track 18b located at the other component. FIGS. 2A and 2B illustrate the above indents. There are other numerous means for engaging the adjuster with the cavity on the main body. There will be a number of the adjusters to fit the different types of portable devices and different models of the portable device such as the different models of the music player. Consequently, the space 19 of the adjuster 1 which caters to the particular size and shape of the portable device, herein the music player, as example, will also vary. To allow for this variation, the sidewalls 15 would have a lateral projecting top wall 20 covering the space between the sidewalls 15 and the space 19 required for a particular music player that is bordered by the ridges 14 and the domelike extension 13 as shown in FIGS. 2, 2C and 2D, the latter two showing two examples of the adjuster 1. For the ipod music player, a slit 21, a horizontal opening, is cut at the bottom wall 7 of the cavity 5 for accommodating the ipod connector 22 as shown in FIGS. 2 and 3. For other music players and other portable devices, this may likewise be a horizontal opening or it can also be a hole or openings of other geometric configuration conforming with the outside surface contour of the respective portable device connector. Raised ridges or fences 23 around the connector 22 (also referred to as first connector) or around the slit 21 are recommended to keep the connector in an inclined upright position conforming with the direction of the slant position of the bottom wall of the cavity for easy connection with the music player. The degree of the slant may vary depending on the desired position of the portable device and the needs of the particular portable device. Consequently, these raised ridges or fences may be designed to be detachable and capable of varying the degree of inclination of the portable device such that a number of these as accessories may be required. On top of the walls of the main body is a planar top cover 24 covering the main body except the cavity. The planar top cover 24 has protruding elements such as a lip 25 laterally protruding beyond the walls 8, 9, and 10 of the main body. Although the top wall 20 and the top cover 24 are shown here in planar configuration, these can be shaped differently according to the manufacturer's discretion.

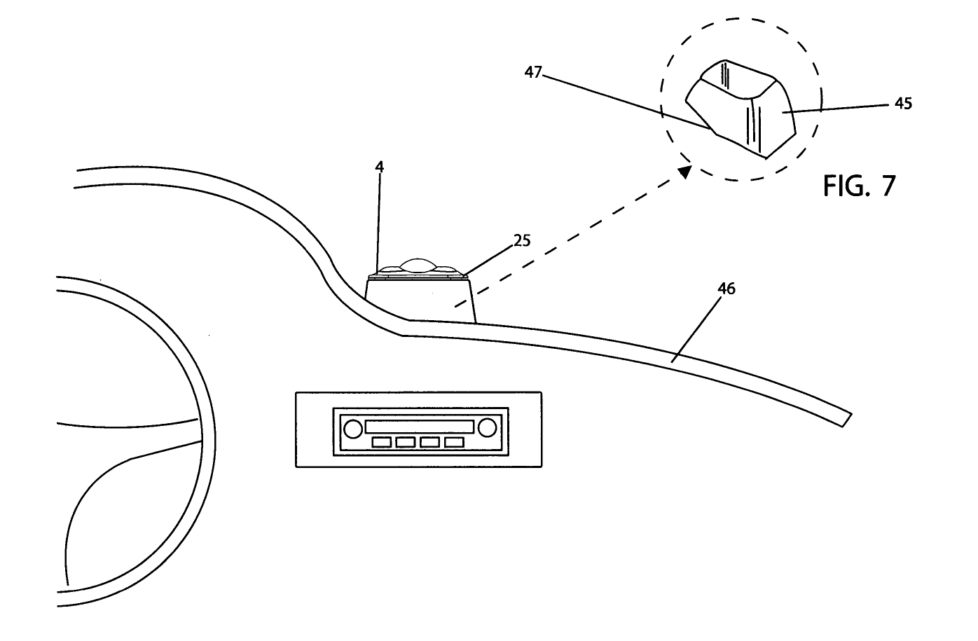

To achieve one purpose of the claimed invention, that of achieving a seamless integration of the cradle on the vehicle without the presence of visible wires dangling at the interior of a vehicle such as outside the dashboard, rear or front compartment, cigarette lighter, radio, etc., it is proposed to install or mount the claimed cradle by either boring an opening at a desired location or part of the vehicle where a portable device is desired or manufacturing the part of the vehicle where a cradle is desired such as the dashboard, for example, with the main body 4 molded on the chosen part of the vehicle. Vehicle here means any medium of transportation. On preexisting vehicles, boring an opening at the chosen part is the only option. For simplicity of illustration only, a mounting of the cradle 100 for a music player on an opening at the dashboard of the vehicle will be used as an example. Here, an opening 44 just enough to accommodate walls 8, 9 and 10 and any cables outside the sidewalls of the main body, is bored on a desired location of a vehicle's dashboard 46 depending on who would be the intended operator of the music player which in most cases, would be the driver. It would be best to remove the dashboard from the vehicle before boring the opening 44 to facilitate the installation of the cradle 100. The installation steps or process herein illustrated is not meant to be strictly followed chronologically but one may choose to do one step before another step depending on the situation. [[One]] process of installation, comprise: threading the cable 38 connected to connector 27 into the hole 12 located on the back wall 10 of the main body; connecting the cable 38 to the circuit board 26 inserting connector 22 into the slit 21 of the cavity 5; snapping the circuit board 26 into the carvings 36 of the clips 35; mounting the main body 4 through the opening 44 on the dashboard; holding the main body on top of the dashboard by the laterally protruding lip 25 surrounding the walls 8,9 and 10 of the main body; snapping the bottom lid 2 into the main body 4, keeping the section of the dashboard bordering the opening 44 situated between the top cover 24 and the bottom lid 2; connecting the cable 38 into an auxiliary port of the vehicle's radio system through the second connector 27; and, reinstalling the dashboard into the vehicle. A cross section of the assembly of the cradle 100 on the dashboard 46 is shown in FIG. 6. After reinstallation, the cradle is ready to operate the portable device which in this example is a music player after the latter is plugged into the first connector 22. If needed, a height and shape adjuster 45 is placed between the dashboard and lip 25 on the top cover of the main body 4 if the top surface of the dashboard is not planar but of a particular shape and slope. The bottom end 47 of the height and shape adjuster fits and conforms with the particular contour of the top surface of the dashboard. An example of this adjuster is shown in FIG. 7. Although more limited in usage, the main body may have its bottom end shaped according to the contour of the dashboard which do away with the need of a height and shape adjuster. The hole 12 may be located at any walls of the main body instead of the back wall. For new vehicles, as stated above, the main body 4 can be molded as a component of the dashboard or as component of any part of a vehicle where a cradle is desired. The assembly of the cradle 100 on a premolded main body would be similar to the process stated above except that the steps of mounting and holding the main body on top of the dashboard is skipped and the removal and reinstallation on the dashboard may not be necessary. For both methods of installation, after the complete installation of the cradle 100, if an adjuster needed, the proper adjuster 1 is inserted into the cavity of the main body 4 and the appropriate portable device, here a music player, fitting the adjuster is laid on the cavity 5 and plugged into connector 22, ready for operation. It is to be noted, as stated earlier, that the cradle 100 may not need an adjuster if the main body 4 is used directly as the holder for the portable device, here a music player. It is also to be noted that new vehicles may also have an opening pre-bored with a detachable lid on any part of a vehicle at a location where a portable device would be desired and the installation in this case will be the same if not similar to the process/steps after an opening had been bored for the main body of the cradle.

With this cradle combined with the process of mounting as described, only the main body 4 or the main body 4 with the height and shape adjuster 45 is seen on the vehicle. The cables will be hidden underneath the part of the vehicle, which as illustrated, underneath the dashboard.

Because of the different types of portable devices where the claimed invention can be used and the different parts of the vehicle where a portable device is desired, it can be expected to have this cradle with the accessories, namely the different adjusters: adjuster 1, height and shape adjuster 45 and the raised ridges or fences for the slit 21 or the connector 22 packaged as a kit for each type of portable device or for the different models of the same portable device.

While the embodiments of the present invention have been described, it should be understood that various changes, adaptations, and modifications may be made therein without departing from the spirit of the invention and the scope of the claims.

1. A cradle for a portable device, comprising:
a main body having side walls, an open bottom and a top cover, the top cover having a cavity for accommodating a portable device, the cavity having sidewalls and a slanting bottom wall to allow the portable device to insert into the cavity in a desired position, the sidewalls of the cavity having supporting means for keeping the portable device in an upright position, the main body having a hollow interior and an opening for allowing a cable to go through; and,
a circuit board assembly comprising a first connector on one end of a circuit board inserting into an opening at the slanting bottom wall of the cavity and a second connector connected to the circuit board by the cable, the circuit board assembly supplying power, receiving and transmitting audio or data or both audio and data signals from the portable device to an external transmitting receiver device on a vehicle.

2. The cradle of claim 1 further comprising an adjuster inserting into the cavity of the main body to fit a particular portable device having a particular size and shape.

3. The cradle of claim 2 wherein the adjuster include the supporting means for keeping the portable device in an upright position instead of the main body.

4. The cradle of claim 2 wherein the adjuster and the main body have corresponding indents for snug fitting the adjuster into the cavity of the main body.

5. The cradle of claim 1 wherein the top cover of the main body has a laterally protruding element beyond the side walls for suspending the main body of the cradle outside and above a desired part of the vehicle.

6. The cradle of claim 1 wherein a portion of a sidewall of the cavity is etched out to provide unobstructed access to the portable device.

7. The cradle of claim 6 wherein the portion of the sidewall is etched out in a convex shape to provide unobstructed access to a portable device with a scroll wheel used for operating the portable device.

8. The cradle of claim 1 wherein the supporting means is a domelike extension providing a back support and raised ridges providing a front support for the portable device.

9. The cradle of claim 1 wherein the first connector on the circuit board assembly or the opening at the slanted bottom wall of the cavity is surrounded by raised ridges or fences to keep the first connector in a desired position for easy connection with the portable device.

10. The cradle of claim 1 wherein the circuit board situates underneath the slanting bottom wall of the cavity and the hollow interior of the main body.

11. The cradle of claim 1 further comprising means for holding the circuit board in place underneath the main body.

12. (canceled)

13. (canceled)

14. The cradle of claim 1 further comprising a height and shape adjuster between the top cover of the main body and a desired part of a vehicle.

15. The cradle of claim 1 wherein the portable device is a personal digital assistant, global positioning system device, cell phone, digital video disk monitor, television screen, monitor for electronic games, tablet personal computer, portable satellite radio or a music player.

16. (canceled)

17. A method for achieving a seamless integration of a cradle for a portable device on a vehicle without the presence of visible wires at the interior of the vehicle using a cradle having a main body including a cavity with sidewalls and a slanted bottom wall having an opening for accommodating a portable device, the main body having an opening for allowing a cable to go through, and a circuit board assembly having a first connector on one end connecting to the opening on the slanted bottom wall, a circuit board and a second connector connected by the cable on another end, comprising:
a) a boring an opening of a size just enough to accommodate a cabled main body of the cradle on a part of the vehicle where the cradle will be mounted;
b) mounting the main body on the opening bored at the part of the vehicle, the main body being held on top of an outside surface of the part by protruding elements on the main body having dimensions greater than the bored opening;
c) connecting the second connector of the circuit board assembly to an auxiliary port of the vehicle's external transmitting receiver device;
d) connecting and inserting the portable device at the cavity of the main body.

18. The method of claim 17 further comprising between the step c) and step d), placing an adjuster at the cavity of the main body.

19. The method of claim further comprising between the step a) and step b), placing a height and shape adjuster between the main body and the part of the vehicle to conform with an outside contour of the part of the vehicle.

20. A cradle for a portable device, comprising:
a main body having side walls, an open bottom and a top cover, the top cover having a cavity for accommodating a portable device, the cavity having sidewalls and a bottom wall, the main body having an opening for allowing a cable to go through and an opening at the bottom wall of the cavity;
a circuit board assembly comprising a first connector on one end of a circuit board inserting into the opening at the bottom wall of the cavity and a second connector connected to the circuit board by the cable, the circuit board assembly supplying power, receiving and transmitting audio signals from the portable device to an external transmitting receiver device on a vehicle;
a removable adjuster inserting into the cavity of the main body to fit a particular model of the music player having a particular size and shape.

21. The cradle of claim 20 further comprising a height and shape adjuster between the top cover of the main body and a desired part of a vehicle.

22. The cradle of claim 20 further comprising supporting means for providing support for the portable device.

23. The cradle of claim 1 further comprising a bottom lid for covering the open bottom of the main body after placement of the circuit board underneath the slanting bottom wall of the cavity.

24. The cradle of claim 23 wherein the bottom lid has means for holding the circuit board.

25. The cradle of claim 1 wherein the main body is of different shape.

26. The cradle of claim 1 wherein the first connector of the circuit board assembly is a universal connector.

27. The cradle of claim 1 wherein the main body is molded on a part of a vehicle.

28. The cradle of claim 1 wherein the slant on the bottom wall of the cavity vary according to the portable device.

29. The cradle of claim 1 wherein the opening on the main body is on a wall.

30. The cradle of claim 9 wherein the raised ridges or fences are detachable.

31. The cradle of claim 9 wherein the raised ridges or fences vary an inclination of the portable device.

32. The method of claim 17 wherein step a) is substituted with pre-boring an opening having a detachable lid on a part of the vehicle where a cradle can be mounted.

33. The method of claim 17 further comprising before step a), disconnecting a part of a vehicle where a portable device is desired and adding reinstalling the part of the vehicle between step c) and d).

34. The method of claim 17 wherein the cradle used for mounting in a vehicle is a cradle having a main body of different shape, the main body including a cavity for holding a portable device with sidewalls and a bottom wall having an opening for accommodating a first connector of a circuit board assembly of the portable device.
